(19) United States
(12) Patent Application Publication
(10) Pub. No.: US 2025/0201634 A1
(43) Pub. Date: Jun. 19, 2025

(54) METHODS AND APPARATUSES FOR IDENTIFYING DEFECTIVE ELECTRICAL CONNECTIONS, AND METHODS FOR GENERATING A TRAINED COMPUTATIONAL MODEL

(71) Applicant: Applied Materials, Inc., Santa Clara, CA (US)

(72) Inventors: Bernhard G. MUELLER, Finsing (DE); Axel WENZEL, Augsburg (DE); Ludwig LEDL, Gröbenzell (DE)

(21) Appl. No.: 18/847,716

(22) PCT Filed: Apr. 5, 2022
(86) PCT No.: PCT/EP2022/058992

§ 371 Date: Sep. 17, 2024

(51) Int. Cl. H01L 21/66; G01R 31/305; G01R 31/66

(52) U.S. Cl. CPC H01L 22/12; G01R 31/305; G01R 31/66

(57) ABSTRACT

A method of identifying defective electrical connections of a substrate is provided, the substrate having a first surface contact and a first electrical connection extending from the first surface contact through the substrate. The method includes: charging the first surface contact by directing an electron beam on the first surface contact; detecting a first secondary electron signal as a function of time during the charging of the first surface contact; inputting input data that comprise or are based on the first secondary electron signal to a trained computational model, particularly to a trained machine learning model; and receiving defect information about the first electrical connection as an output from the trained computational model. Further described are an apparatus for identifying defective electrical connections of a substrate and a computer-readable storage medium storing a trained computational model.

### FIELD

The present disclosure relates to methods and apparatuses for identifying defective electrical connections that extend through a substrate, particularly through an advanced packaging (AP) substrate or a panel-level packaging (PLP) substrate. More particularly, embodiments described herein relate to the contactless testing of electrical connections in a substrate using an electron beam in combination with machine learning techniques and artificial intelligence, particularly for identifying and characterizing defects, such as shorts, opens, and/or leakages.

### BACKGROUND

In many applications, it is necessary to inspect a substrate to monitor the quality of the substrate. Since defects may occur during the processing of the substrates, e.g. during the coating of the substrates, an inspection of the substrate for reviewing the defects and for monitoring the quality of the displays may be beneficial.

Semiconductor substrates and printed circuits boards for the manufacture of complex microelectronic or micro-mechanic components are typically tested before, during, and/or after manufacturing for determining defects, such as “short defects” or “open defects”, in conductive paths and interconnects extending on or through substrate layers. For example, substrates for the manufacture of complex microelectronic devices may include a plurality of interconnect paths meant for connecting semiconductor chips that are to be mounted on the substrate.

Various methods for testing such components are known. For example, contact pads of a component to be tested may be mechanically contacted with a contact probe, in order to determine whether the component is defective or not. However, since the components and the contact pads are becoming smaller and smaller due to the progressing miniaturization of components, contacting the contact pads with a contact probe may be difficult, and there may even be a risk that the device under test gets damaged during the testing.

The complexity of packaging substrates is increasing and design rules (feature size) are decreasing substantially. Within such substrates the surface contacts (for later flip chip or other chip mounting) are connected to other surface contacts on the packaging substrate to interconnect semiconductor (or other) devices. Standard methods like electrical-mechanical probing for electrical test cannot satisfy the requirements of volume production testing as the throughput decreases (higher number of test points) and contacting reliability decreases (smaller contact size). Beyond the reduced size and the problem of potentially damaging contact pads, the topography of the packaging substrates results in difficulties for other test methods, like test methods utilizing capacitive detectors or electrical field detectors, because such methods beneficially have a small mechanical spacing.

Accordingly, it would be beneficial to provide testing methods and testing apparatuses that are suitable for reliably and quickly identifying defects in electrical connections of complex microelectronic devices.

### SUMMARY

In light of the above, methods and apparatuses for identifying defective electrical connections of a substrate are provided according to the independent claims. Further provided are methods of generating a trained computational model for identifying defective electrical connections as well as a computer-readable storage medium storing a trained computational model. Further aspects, advantages, and beneficial features are apparent from the dependent claims, the description, and the accompanying drawings.

According to one aspect, a method for identifying defective electrical connections of a substrate is provided, the substrate having a first surface contact and a first electrical connection extending from the first surface contact. The method includes (a) charging the first surface contact by directing an electron beam on the first surface contact; (b) detecting a first secondary electron signal as a function of time during the charging of the first surface contact; (c) inputting input data that comprise or are based on the first secondary electron signal to a trained computational model, particularly to a trained machine learning model; and (d) receiving defect information about the first electrical connection as an output from the trained computational model.

The input data may further include position information about the first surface contact on the substrate. The trained computational model may be configured to provide the defect information as an output based on input data that include the first secondary electron signal generated during the charging of the first surface contact and the position information of the first surface contact. The input data may optionally include further information or further input parameters, such as information about the substrate and/or information about the first electrical connection, e.g. material information and/or electrical properties of the first electrical connection that may influence the first secondary electron signal that is generated during the charging.

In some embodiments, the substrate is an advanced packaging substrate (AP substrate), a panel-level packaging (PLP) substrate, or a wafer-level packaging (WLP) substrate.

According to another aspect, a method of generating a trained computational model, particularly a trained machine learning model, for identifying defective electrical connections of a substrate is provided. The trained computational model can then be used for identifying defective electrical connections in accordance with any of the methods described herein. The method includes: charging a first surface contact by directing an electron beam on the first surface contact; detecting a secondary electron signal as a function of time during the charging of the first surface contact; determining associated defect information about a first electrical connection that extends from the first surface contact; providing a first training data set including input data and the associated defect information, the input data including or being based on the secondary electron signal; and generating the trained computational model by training a computational model with the first training data set and with a plurality of further training data sets provided analogously for a plurality of further surface contacts having a respective electrical connection extending therefrom.

The computational model may be a machine learning model that is trained with the plurality of training data sets based on a machine learning algorithm.

In some embodiments, the first training data set includes (i) the secondary electron signal as a function of time generated during the charging of the first surface contact (directly or in a processed form), (ii) position information about a location of the first surface contact, and (iii) associated defect information specifying whether or not the first electrical connection extending from the first surface contact includes a defect. The associated defect information can be determined via one or more voltage contrast measurements. A plurality of further training data sets generated in an analogous way by testing a plurality of surface contacts (having defective and/or non-defective electrical connections extending therefrom) may be used for training a computational model, such that a trained computational model is provided that is able to identify defects based on input data that include SE signals as a function of time.

According to another aspect, an apparatus that is configured to identify defective electrical connections of a substrate in accordance with any of the methods described herein is provided.

An apparatus for identifying defective electrical connection of a substrate as described herein may include: a vacuum chamber that houses a stage for placement of the substrate; an electron source configured to generate an electron beam; a scan deflector for directing the electron beam on a first surface contact for charging the first surface contact; a secondary electron detector configured to provide a first secondary electron signal as a function of time during the charging of the first surface contact; and a data processing unit with a memory storing a trained computational model that is configured to receive input data comprising or being based on the first secondary electron signal and to provide defect information about a first electrical connection that extends from the first surface contact as an output.

According to another aspect, a computer-readable storage medium storing a trained computational model is provided, particularly a trained machine learning model. The trained computational model is configured to receive input data including or being based on a secondary electron signal detected as a function of time during charging of a surface contact, and to provide, in response thereto, defect information about an electrical connection that extends from the surface contact.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus and methods for manufacturing the apparatuses and devices described herein. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of an apparatus for identifying defective electrical connections according to embodiments described herein;

FIGS. 2A-2C schematically illustrate methods of testing electrical connections according to embodiments described herein;

FIG. 2D shows some examples of secondary electron signals detected as a function of time during the charging of respective surface contacts;

FIG. 3 schematically illustrates a method of identifying defective electrical connections according to embodiments described herein;

FIG. 4 schematically illustrates a method of identifying defective electrical connections according to embodiments described herein;

FIG. 5 is a block diagram illustrating a method of identifying defective electrical connections utilizing a trained machine learning model according to embodiments described herein;

FIG. 6 is a flowchart illustrating a method of identifying defective electrical connections according to embodiments described herein; and

FIG. 7 is a flowchart illustrating a method of generating a trained machine learning model for identifying defective electrical connections according to embodiments described herein.

### DETAILED DESCRIPTION

Reference will now be made in detail to the various exemplary embodiments, one or more examples of which are illustrated in each figure. Each example is provided by way of explanation and is not meant as a limitation. For example, features illustrated or described as part of one embodiment can be used on or in conjunction with other embodiments to yield yet further embodiments. The intention is that the present disclosure includes such modifications and variations. Within the following description of the drawings, same reference numbers refer to same components. Only the differences with respect to the individual embodiments are described. The structures shown in the drawings are not necessarily depicted true to scale but rather serve the better understanding of the embodiments.

The complexity of packaging substrates has been increasing for years, with the aim of reducing the space requirements of semiconductor packages. A conventional semiconductor package is manufactured from a semiconductor wafer before being diced and packaged. The semiconductor package can then be mounted, together with other microelectronic components, on a printed circuit board (PCB).

For reducing the manufacturing costs and the space requirements, packaging techniques have developed further in recent years, and techniques such as 2.5D ICs, 3D-ICs, wafer-level packaging (WLP), e.g. fan-out WLP or fan-in WLP, and panel-level packaging (PLP) were proposed. In WLP techniques, the integrated circuit is packaged before dicing, while still being part of the wafer. Accordingly, the resulting package has practically the same size as the wafer.

“2.5D integrated circuits” (2.5D ICs) and “3D integrated circuits” (3D ICs) combine multiple dies in a single integrated package. Here, two or more unpackaged dies are placed on a packaging substrate, e.g. on a silicon interposer. In 2.5D ICs, the dies are placed on the packaging substrate side-by-side, whereas in 3D ICs at least some of the dies are placed on top of each other. The assembly can be packaged as a single component, which reduces costs and size as compared to a conventional 2D circuit board assembly.

A packaging substrate typically includes a plurality of device-to-device electrical interconnect paths meant for providing electrical connections between the dies that are to be placed on the packaging substrate. The device-to-device electrical interconnect paths may extend through a body of the packaging substrate in a complex connection network, vertically (perpendicular to the surface of the packaging substrate) and/or horizontally (parallel to the surface of the packaging substrate) with end points (referred to herein as surface contacts) exposed at the substrate surface.

In order to reduce manufacturing costs, panel-level-substrates are manufactured that are configured for the integration of a plurality of devices (e.g., chips/dies that may be heterogeneous, e.g. may have different sizes and configurations) in a single integrated package. A panel-level substrate typically provides chip sites for a plurality of chips/dies to be placed on a surface thereof, e.g. on one side thereof or on both sides thereof, as well as a plurality of device-to-device electrical interconnect paths extending through a body of the packaging substrate. Notably, the size of a panel-level-substrate is not limited to the size of a wafer. For example, a panel-level-substrate may be rectangular or have another shape. Specifically, a panel-level-substrate may provide a surface area larger than the surface area of a typical wafer, e.g., 1000 cm² or more. For example, the panel-level substrate may have a size of 30 cm×30 cm or larger, 60 cm×30 cm or larger, 60 cm×60 cm or larger, or larger than that.

An advanced packaging (AP) substrate provides device-to-device electrical interconnection paths on or within a wafer, such as a silicon wafer. For example, an AP substrate may include Through Silicon Vias (TSVs), e.g., provided in a silicon interposer, or other conductor lines extending through the AP substrate. A panel-level-packaging substrate is typically provided from a compound material, for example material of a printed circuit board (PCB) or another compound material, including, for example ceramics and glass materials.

Conventional testing apparatuses may not be adapted or suitable for the testing of advanced packaging substrates or panel-level packaging substrates due to the geometry and density of the surface contacts and/or due to the size of the packaging substrate which may be different from the size of conventional dies or printed circuit boards. The present disclosure relates to methods and apparatuses for identifying defects in a substrate with a plurality of densely arranged surface contacts and a plurality of electrical connections extending between two or more surface contacts, respectively. In particular, the methods and apparatus described herein may be suitable for testing packaging substrates that are configured for the integration of a plurality of devices in one integrated package, and that may include at least one device-to-device electrical interconnect path extending between a first surface contact and at least one second surface contact.

A “surface contact” as used herein may be understood as an end point of an electrical interconnect path (also referred to herein as an “electrical connection”) that is exposed at a surface of the substrate, such that an electron beam can be directed on the surface contact for contactlessly charging or probing the surface contact. A surface contact may be meant for electrically contacting a chip/die that is to be placed on the surface of the substrate, e.g. via soldering. For example, a surface contact may be configured as a solder bump.

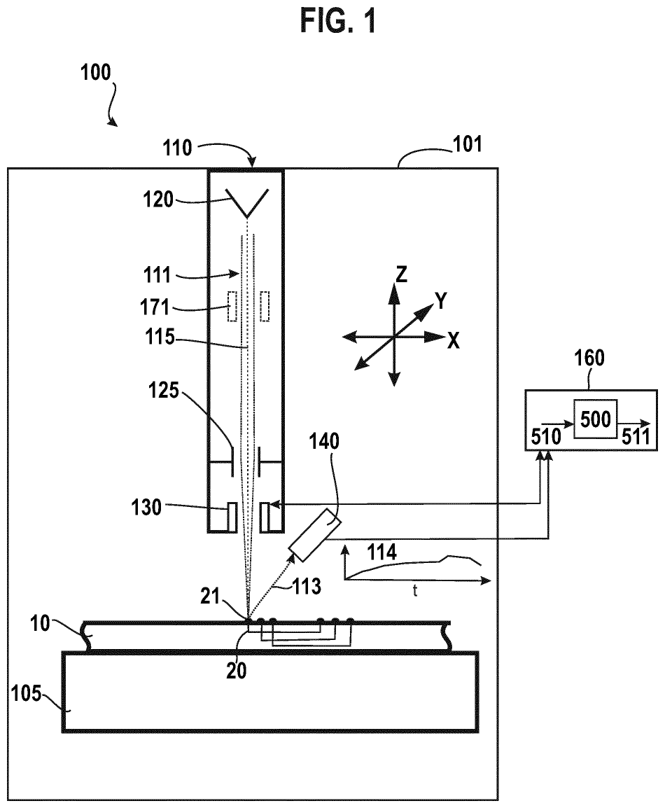

FIG. 1 schematically shows an apparatus 100 for identifying defects in electronic connections, such as interconnect paths and/or via extending through a substrate 10, according to embodiments described herein. The apparatus 100 may include a vacuum chamber 101 that may be a testing chamber specifically configured for testing or that may be one vacuum chamber of a larger vacuum system, e.g. a processing chamber of a substrate manufacturing or processing system. For example, the apparatus may be configured as an in-line inspection apparatus that is integrated in a substrate processing system.

The vacuum chamber 101 may house a stage 105, e.g. a movable stage, for placing the substrate 10 thereon. The apparatus 100 further includes an electron source 120 for generating an electron beam, a scan deflector 130 for deflecting the electron beam to a predetermined position on the substrate, and an electron detector 140 for detecting secondary electrons emitted from the substrate upon impingement of the electron beam.

As it is schematically shown in FIG. 1, the substrate 10 includes a first surface contact 21 and a first electrical connection 20 extending from the first surface contact 21 through the substrate, e.g. to one or more further surface contacts that may be located on the same surface of the substrate as the first surface contact 21 or that may be located on an opposite substrate surface (not shown in the figures). The substrate 10 may include a plurality of surface contacts and a plurality of electrical connections extending from the plurality of surface contacts, for example 10,000 or more electrical connections, particularly 100,000 or more electrical connections, or even 1,000,000 or more electrical connections. According to methods described herein, the plurality of electrical connections extending from the plurality of surface contacts may be inspected for identifying defective connections.

The apparatus 100 includes an electron beam column 110 with an electron source 120 configured to generate an electron beam 111 that propagates along an electron beam path 115 toward the substrate, e.g. a thermal field emitter. The electron beam 111 can be directed, particularly focused, on a predetermined location on the substrate. Specifically, the apparatus 100 may include a scan deflector 130 configured to direct the electron beam 111 on a surface contact, e.g. on the first surface contact 21 as depicted in FIG. 1. By directing the electron beam 111 on a surface contact, the surface contact and the electrical connection that extends from the surface contact can be charged, particularly negatively charged.

In some embodiments, the electron beam 111 can be focused on the surface of the substrate 10, e.g. by a focusing lens 125, particularly a magnetic and/or electrostatic focusing lens. Specifically, the focusing lens 125 may be configured to focus the electron beam 111 on the first surface contact 21 for charging the first surface contact 21 in a targeted way.

Further beam-optical components 171 may optionally be provided along the electron beam path 115 for influencing the electron beam 111, such as, e.g., a condenser lens and/or an aberration corrector, e.g. a stigmator and/or a chromator.

In some implementations, the electron energy of the electron beam 111 (i.e., the landing energy of the electrons of the electron beam 111 on the substrate surface) may be above the neutral charging point. The “neutral charging point” as used herein refers to an electron energy of the electron beam that does not change the charges on an uncharged surface contact when the electron beam impinges thereon, because the amount of signal electrons emitted from the substrate upon impingement essentially corresponds to the amount of electrons transferred to the surface contact by the electron beam. The neutral charging point may, in some implementations, correspond to an electron energy of the electron beam 111 between 1.5 keV and 3 keV, particularly about 2 keV.

Electrons impinging on the substrate with a landing energy above the neutral charging point may have a reduced probability of generating secondary electrons emitted from the substrate, such that the substrate is negatively charged when hit by an electron beam with an electron energy above the neutral charging point. Electrons impinging on the substrate with a landing energy below the neutral charging point may have an increased probability of generating secondary electrons that leave the substrate, such that the substrate can be discharged when hit by an electron beam with an electron energy below the neutral charging point.

In some embodiments, the electron energy of the electron beam 111 may be 5 keV or more, particularly about 10 keV, particularly an electron energy which is above the neutral charging point. Therefore, the amount of signal electrons emitted from the substrate upon impingement is typically smaller than the amount of electrons transferred to the substrate by the electron beam 111. Accordingly, negative charges can be transferred to a surface contact by the electron beam 111, such that the surface contact, together with the electrical connection extending therefrom, can be negatively charged. “Charging” as used herein may particularly relate to the application of negative charges, i.e. electrons, to a surface contact to cause a predetermined (negative) electric potential of the electrical connection that extends from the surface contact.

The apparatus 100 further comprises an electron detector 140 configured to detect secondary electrons 113 emitted from the substrate 10, particularly during the impingement of the electron beam 111. The electron detector 140 may be configured to detect the secondary electrons (SEs) emitted during the charging of the first surface contact 21 with the electron beam 111 to provide a secondary electron signal 114 as a function of time during the charging. A “secondary electron signal” or “SE signal” as used herein may refer to the number of secondary electrons emitted by a surface contact as a function of time in the course of the charging of the surface contact. The SE number depends on the surface voltage. Specifically, the secondary electron signal 114 includes information about the time dependency of the surface voltage during the charging. FIG. 1 schematically indicates a secondary electron signal 114 as a graph showing the detected SE yield (x-axis) as a function of time (y-axis) during the charging. The SE yield may be measured at discrete time periods during the charging (e.g., every 100 nm until reaching a saturation value) to provide the secondary electron signal 114 as a (discrete) function of time.

In some embodiments, the electron detector 140 includes an Everhard-Thornley detector. An energy filter for the signal electrons may be arranged in front of the electron detector 140, particularly in front of the Everhard-Thornley detector. The energy filter may include, e.g., a grid electrode configured to be set on a predetermined potential. The energy filter may allow the suppression of low-energy signal electrons. The energy filter may be set for optimized voltage contrast detection. Accordingly, the signal strength detected by the electron detector 140 may depend on the energy of the signal electrons which indicates if a surface contact point is provided at a predetermined electric potential or not.

Notably, if an image of a surface area is taken by a conventional scanning electron microscope, only the SE yield per pixel is generally of interest, not a time dependency of an SE signal during a charging process, which distinguishes embodiments disclosed herein from conventional imaging scanning electron microscopes.

The secondary electron signal 114 generated during the charging with the electron beam 111 is time dependent, because the amount of negative charges on the first surface contact increases during the charging, which increases the secondary electron yield due to the increasingly negative potential of the first surface contact. Further, the temporal course of secondary electron signal 114 depends on electrical characteristics of the first electrical connection 20, such as the capacitance of the first electrical connection and/or the cross-capacitance in relation to neighboring electrical connections. Specifically, a small-capacitance electrical connection charges up quickly, such that the secondary electron signal 114 rises quickly over time, whereas a large-capacitance electrical connection charges up slowly, such that the secondary electron signal 114 rises slowly over time. The secondary electron signal 114 over time during the charging of a surface contact may generally follow an S-shaped curve, i.e., a slow rise in the beginning upon initial impingement of the electron beam, a steeper rise in a central section, and a slow rise toward a saturation value, the saturation value corresponding to an electric potential of the first electrical connection that does not longer increase by the impingement of the electron beam (as there are hardly any secondary electrons left which could leave the surface). However, in reality, the time dependency of the secondary electron signal may show deviations from such an S-curve, e.g. due to cross-capacitance effects, interactions between neighboring surface contacts, charge build-up effect, defects and/or other effects.

If an electrical connection is interrupted due to a defect (i.e., if an “open” defect exists), the capacitance of the respective electrical connection is smaller than expected, which will lead to an unexpectedly quick rise of the secondary electron signal over time. If an electrical connection is shorted to another electrical connection due to a defect (i.e., if a “short” defect exists), the capacitance of the respective electrical connection is larger than expected, which will lead to an unexpectedly slow rise of the secondary electron signals over time during the charging. Therefore, the secondary electron signal generated as a function of time during the charging of a surface contact can provide defect information about the electrical connection that is connected to the surface contact, if it is known how the SE signal of the respective electrical connection in a faultless case would look like.

Reliably determining defect information about an electrical connection based on a secondary electron signal generated during charging may be challenging, because the time dependency of the secondary electron signal generated during charging may depend on a plurality of factors, such as on a defect class of the defect that may be present and on a location of the respective surface contact on the substrate. For example, a surface contact that is located near a corner or near an edge of the substrate may generally generate a different secondary electron signal upon charging than a surface contact located in a center area of substrate, e.g. due to variations in the density of surrounding surface contacts which may cause cross-capacitance effects that change the temporal behavior of the SE yield. In particular, the electrical characteristics of an electrical connection and hence the SE signal generated upon charging may depend on the position of the respective surface contact from which the electrical connection extends.

In some embodiments, each surface contact of a plurality of surface contacts of a substrate or at least subsets of surface contacts having a corresponding “position identifier” may generate—if not defective—a respective characteristic secondary electron signal upon charging thereof. The position dependency of the time dependencies of secondary electron signals may make a reliable determination of defect information about electrical connections particularly challenging.

In view of the above, apparatuses and methods described herein provide a way of reliably identifying defective electrical connections of a substrate, even if the substrate has a huge number of surface contacts that may respectively generate characteristic secondary electron signals during charging thereof.

As itis schematically depicted in FIG. 1, the apparatus 100 includes a data processing unit 160, such as a computer, that includes a trained computational model 500, e.g., stored in a memory thereof, that is configured to receive input data 510 comprising or being based on the first secondary electron signal 114 as a function of time and that is configured to provide defect information about the first electrical connection 20 as an output.

In some embodiments, the trained computational model is a machine learning model, particularly a deep learning-based model, that has been previously trained with respective training data sets as described hereinbelow. In some embodiments, the machine learning model may be based on a neural network, particularly on a deep neural network (DNN) having at least one hidden layer, e.g. a deep neural network with three or more layers. Also neural networks with a smaller number of layers can be utilized, depending on the complexity of the substrate and the number of parameters influencing the SE signals during charging. The description herein referring to a deep neural network (DNN) may similarly be applied to a neural network (NN) in general and other artificial intelligence (AI) computational models, particularly machine learning (ML) computational models. Specifically, the computational model may include an input layer, an output layer, and one or more hidden layers between the input and output layer. However, the computational model used according to embodiments herein is not limited to being based on a DNN with a hidden layer, and the relation between the input data (particularly, including the secondary electron signal and optionally the location of the respective surface contact) and the output data (particularly, including the defect information) may be more straightforward in some embodiments. For example, the input data and the defect information may be linked via an if-else-based relation that provides a mapping between one or more characteristics retrieved from the SE signal and the position information of the respective electrical contact on the one hand and the respective defect information on the other hand. In other words, the computational model is not limited to a deep learning-based model with a plurality of layers.

The trained computational model 500 is configured to receive the input data 510 that includes or is based on the first secondary electron signal 114. For example, the input data 510 may include the secondary electron signal 114 in an unprocessed form or in a processed form, e.g., one or more parts of the secondary electron signal 114 (e.g., an initial part until a predetermined threshold potential of the first surface contact is reached; or a variation or steepness value of the secondary electron signal 114 at one or more predetermined times during the charging). In some embodiments, the input data 510 may include the secondary electron signal 114 as a function of time from the beginning of the charging up to a certain point in time, e.g. until reaching a predetermined potential.

The input data 510 may optionally include further information, particularly position information about the location of the first surface contact 21 on the substrate. For example, the input data 510 may include an (absolute) position of the first surface contact 21 on the substrate (e.g., the x- and y-coordinates on the substrate surface) or a relative position of the first surface contact 21 with respect to one or more further surface contacts (e.g., “corner position”, “edge position”, “center position”, the number of direct neighbor contacts, etc.). In some embodiments, the position information may include a position identifier that characterizes the position of the first surface contact among the plurality of surface contacts and/or that characterizes the position of the first electrical connection among the plurality of electrical connections. In an example, the position identifier is “n, m” for a surface contact in an n^{th} row and an m^{th} column of surface contacts of a two-dimensional array of surface contacts, and/or the position identifier is “x”, wherein x identifies a subgroup of surface contacts having common electrical characteristics to which the surface contact being tested belongs, n, m, x being integers.

In some embodiments, both the SE signal as a function of time during the charging and the position information of the respective surface contact may be used as input parameters (i.e., being part of the input data) for reliably retrieving the defect information as an output from the computational model. As mentioned above, each surface contact position may lead to a respective characteristic SE signal, or respective subgroups of surface contacts may be characterized by a respective typical SE signal, such that a defect information can be reliably retrieved if both the “SE signal” and the “position information” are given as input parameters to the computational model.

Optionally, the input data that are input to the computational model may include any one or more of the following information: (1) Information about the substrate, particularly a substrate type, a substrate material, one or more substrate layer materials, a substrate design rule and/or a substrate identifier. For example, the substrate identifier may define the electrical connections and/or surface contacts that are present on a specific substrate type, e.g., the number and arrangement of electrical connections. If a substrate of the same substrate identifier has already been previously tested multiple times and the computational model has been trained with training data sets retrieved by said testing, the substrate identifier being part of the input data can improve the reliability of the retrieved defect information. (2) Information about the first electrical connection, particularly a capacitance value, a cross-capacitance value that provides information about the cross-capacitance in relation to neighboring electrical connections, a number of surface contacts that are connected to the first electrical connection, a number of neighboring surface contacts and/or a connection identifier that characterizes the type, arrangement and/or electrical characteristics of an electrical connection. For example, if an electrical connection having the same connection identifier has already been previously tested multiple times and the computational model has been trained with training data sets retrieved by said testing, the connection identifier being part of the input data can improve the reliability of the retrieved defect information.

The trained computational model 500 may be configured to provide, as an output, defect information about the first electrical connection 20. In some embodiments, which can be combined with other embodiments described herein, the defect information that is provided by the trained computational model includes information as to whether the first electrical connection seems defective or not. In particular, the defect information may include a binary defect value (e.g., “0”=“no defect”; “1”=“defect”). Optionally, if a defect is detected, the defect information may further include a defect class, for example short defect, open defect or leakage defect. Alternatively or additionally, if a defect is detected, the defect information may include a defect location that locates the position of the defect at or in the substrate. In some embodiments, the defect location may specify the position of the defective electrical connection at or in the substrate (e.g., a “position identifier” that identifies the defective electrical connection among the plurality of electrical connections of the substrate). In some embodiments, the defect location may further identify a position of the defect along the defective electrical connection (e.g., localizing the defect position between two specific surface contacts, or localizing the defect at an intersection between two specific electrical connections, e.g., in the case of a short defect). Alternatively or additionally, the defect information may further include reliability information that characterizes a reliability of the defect information. For example, the trained computational model may, in some cases, detect a defect and/or a specific defect class with a high reliability of 90% or more. In other cases, e.g., if the secondary electron signal 114 only slightly deviates from an expected secondary electron signal of a non-defective connection, the trained computational model may not be able to identify a defect with a high reliability. For example, the trained machine learning model may provide the defect information including a reliability value (e.g., in %) that indicates the reliability that the detected defect and/or a detected defect class or defect position are actually present.

In some embodiments, which can be combined with other embodiments described herein, the substrate has a plurality of surface contacts with a respective electrical connection extending therefrom, particularly 10,000 or more, 100,000 or more, or even 1,000,000 or more surface contacts, which are successively tested in accordance with the testing methods described herein. In particular, each of the plurality of surface contacts may be tested as follows: The surface contact is charged by directing the electron beam thereon, e.g. by deflection with the scan deflector 130 (stage (a)). The SE signal generated during the charging of the respective surface contact is detected as a function of time with the electron detector 140 (stage (b)). Input data is generated that is based on the SE signal and optionally on the position of the respective surface contact, and the input data is input to the trained computational model 500 (stage (c)). Defect information about the electrical connection that extends from the respective surface contact is received as an output from the trained computational model 500 (stage (d)). Accordingly, a plurality of electrical connections can be tested in succession by deflecting the electron beam on a surface contact that is connected to the respective electrical connection, by detecting the SE signal as a function of time during the charging, and by analyzing the SE signal utilizing the trained computational model 500, particularly a trained machine learning model, more particularly the trained deep-learning based model.

In some embodiments, the substrate 10 is an advanced packaging substrate or a panel-level packaging substrate configured to provide a multi-device in-package-interconnection, the first electrical connection being a device-to-device electrical interconnect path. For example, the substrate may be a panel level packaging (PLP) substrate, a wafer level packaging (WLP) substrate or a micro-LED substrate. The packaging substrate may include a plurality of 1,000,000 or more surface contacts with respective electrical connections extending therefrom, which may all be tested in succession.

In some implementations, the plurality of surface contacts are distributed over a surface area of the substrate or a surface sub-area of the substrate of 16 cm² or more, particularly 25 cm² or more, more particularly 100 cm² or more, or even 225 cm² or more. The method may include successively deflecting the electron beam 111 with the scan deflector 130 on the plurality of surface contacts for successively charging and testing the electrical connections extending therefrom utilizing the trained computational model.

In some embodiments, the scan deflector 130 may provide a deflection area (i.e., a surface area of the substrate that can be reached by deflecting the electron beam with the scan deflector 130, without a movement of stage 105) of 16 cm² or more, particularly 100 cm² or more, more particularly 225 cm² or more. A large deflection area allows a quick and accurate testing of a large number of electrical connections, since there is no need to move the substrate for testing the plurality of electrical connections. In particular, at least one complete chip site on the substrate surface can be tested by deflecting the electron beam on the surface contacts of the chip site, without a stage movement.

The trained computational model 500 may be generated in a preceding stage of training as follows: A computational model, particularly a machine learning model, is trained with a plurality of training data sets by a machine learning algorithm. Each training data set includes input data (including or being based on the SE signal detected as a function of time during the charging of a surface contact) and defect information about the electrical connection extending from said surface contact that is associated to said input data. The input data may optionally include any of the above-mentioned further input parameters, particularly a position information about the location of the respective surface contact.

After the generation of the trained computation model 500, the trained computational model 500 model can be used for reliably and quickly checking—based on SE signals generated during charging—, whether specific electrical connections are defective or not.

In some embodiments, which can be combined with other embodiments described herein, the apparatus further includes a discharging device for discharging at least a portion of the substrate, particularly for discharging the first surface contact before and/or after the charging thereof. For example, the first surface contact can be discharged before the charging, in order to ensure that the charging starts from a predetermined electrical potential of the first surface contact. For example, if a plurality of charges were already present on the first surface contact before the charging, the secondary electron signal 114 would look different than expected due to the existing charges which influence the SE yield. Therefore, discharging the first surface contact before the charging and inspection may be beneficial. In particular, each of a plurality of surface contacts may be discharged before the charging and inspection thereof.

Alternatively or additionally, the first surface contact may be discharged after the charging and inspection of the first surface contact. The discharging after the inspection reduces or avoids an accumulation of charges on the surface of the substrate, which may distort the results of subsequent inspection measurements. In particularly, charges on the surface of the substrate may deflect the electron beam and/or may affect the SE signal that is detected by the electron detector, e.g. if a charged surface contact is arranged in the vicinity of the first surface contact being currently tested. Therefore, discharging the first surface contact after the charging and inspection may be beneficial. In particular, each of a plurality of surface contacts may be discharged after the charging and inspection thereof. In particular, each surface contact of a plurality of surface contacts may be discharged both before and after the inspection.

In some embodiments, the discharging device may include any of a second electron source configured to generate a second electron beam for discharging, an electron flood gun configured to discharge a large surface area of the substrate, and/or a UV discharging lamp. The second electron source may be configured to generate the second electron beam having a second electron energy different from the electron energy of the electron beam 111. In particular, the second electron energy of the second electron beam may be below the neutral charging point, e.g. 2 keV or less, such as about 1.5 keV, such that the second electron beam can be used for removing charges from the substrate.

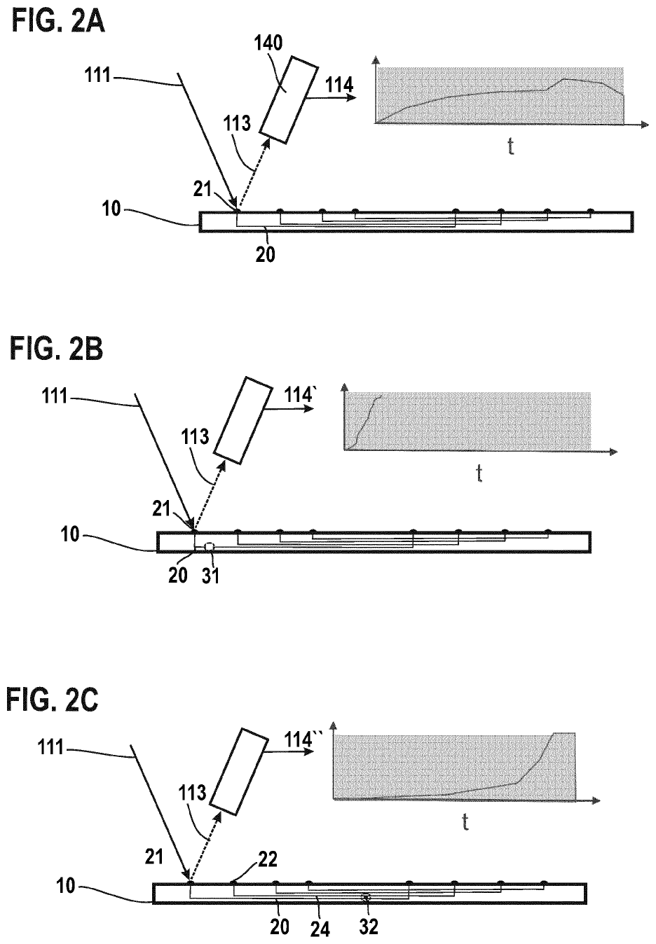

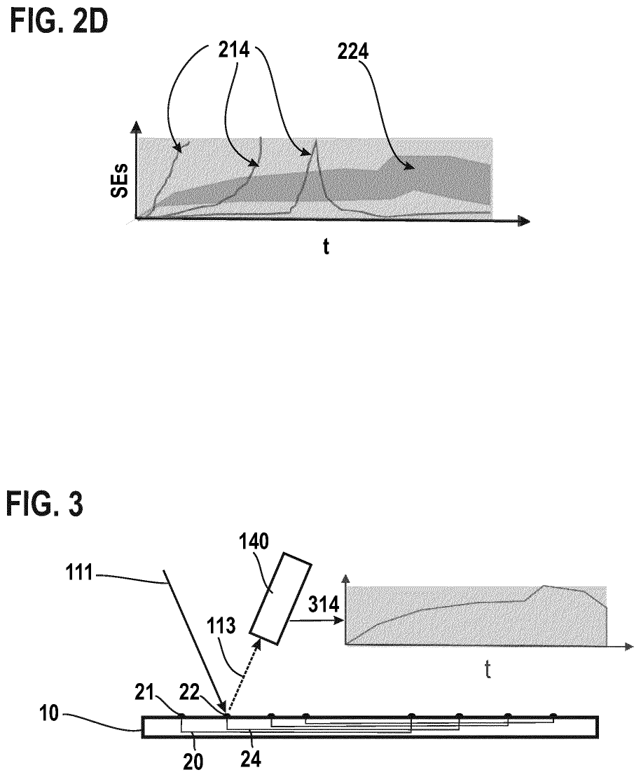

FIGS. 2A-2C schematically illustrate methods of identifying defective electrical connections. FIG. 2A shows the testing of a first electrical connection 20 extending from a first surface contact 21, wherein the first electrical connection 20 is not defective. The electron beam 111 is directed on the first surface contact 21 for charging the first surface contact 21, and secondary electrons 113 emitted from the first surface contact are detected with the electron detector 140 during the charging. A first secondary electron signal 114 that corresponds to the SE yield as a function of time during the charging is detected and is input (directly or in processed form) as part of input data to the trained computational model. The input data may further include a position identifier or another position information about the first surface contact 21 or the first electrical connection 20 under test. In the example of FIG. 2A, the first electrical connection 20 is not defective, resulting in a characteristic time dependency of the first secondary electron signal 114 (note: the time dependency of an SE yield typically depends on the position of the tested electrical connection), such that the trained computational model can determine, based on the input data, that the first electrical connection is not defective (“no defect”).

In particular, the trained computational model may have been previously trained with training data sets retrieved by testing of a plurality of non-defective (and defective) electrical connections having the same position identifier as the first electrical connection, such that the trained computational model can recognize, based on the input data, whether the first electrical connection 20 is defective or not. In some embodiments, an absolute SE yield at one or more times during charging, a steepness of the SE curve at one or more times during charging, an end potential and/or a characteristic shape of the SE signal over time may provide indications to the trained computational model as to whether the first electrical connection is defective or not, and what defect class may be present.

In some embodiments, the trained computational model may recognize that the first electrical connection 20 is defective, if the secondary electron signal 114 is partially and/or entirely out of a predetermined range 224 that is characteristic of SE signals of non-defective electrical connections extending from surface contacts having the same position identifier and/or same electrical characteristics. The predetermined range 224 associated to a specific position identifier can be defined by the computational model by training with a plurality of training data sets that have the same position identifier. For example, the predetermined range 224 may be defined by the computational model as a range around a typical (e.g., average) secondary electron signal over time of non-defective electrical connections having the same position identifier.

FIG. 2B shows the testing of the first electrical connection 20 extending from the first surface contact 21, if the first electrical connection 20 is defective. Specifically, the first electrical connection 20 depicted in FIG. 2B is interrupted, i.e. includes an open defect 31. Therefore, the capacitance of the first electrical connection is reduced, which leads to a quicker rise of the detected secondary electron signal 114′, because the first electrical connection charges up more quickly. The trained computational model can recognize from the input data that includes the secondary electron signal 114′ that the first electrical connection 20 is defective and includes an open defect 31. Further, the reliability of the defect information and the defect position can optionally be included in the output data that are provided by the trained computational model.

The secondary electron signal 114′ has an unexpectedly high steepness or gradient, which may be an indication for the trained computational model that the first electrical connection is defective, particularly interrupted. Alternatively or additionally, the trained computational model may recognize that the secondary electron signal 114′ extends out of a predetermined range 224 that is defined by the computational model for non-defective electrical connections associated to the same position identifier based on training with a plurality of training data sets.

FIG. 2C shows the testing of the first electrical connection 20 extending from the first surface contact 21, if the first electrical connection has another defect. Specifically, the first electrical connection 20 depicted in FIG. 2C is shorted to a second electrical connection 24, i.e. includes a short defect 32. Therefore, the capacitance of the first electrical connection is increased, which leads to a slower rise of the detected secondary electron signal 114″, because the first electrical connection charges up more slowly. The trained computational model can recognize from the input data that include the secondary electron signal 114″ that the first electrical connection 20 is defective and includes a “short” defect 31.

The secondary electron signal 114″ has an unexpectedly slow steepness or gradient in an initial section, which may be an indication for the trained computational model that the first electrical connection is defective, particularly shorted. Alternatively or additionally, the trained computational model may recognize that the secondary electron signal 114″ extends out of the predetermined range 224 that is defined by the computational model for non-defective electrical connections associated to the same position identifier based on training with a plurality of training data sets.

If a short defect is detected, one or more surface contacts of neighboring electrical connections can subsequently be charged with the electron beam 111, in order to further characterize the defect, e.g. for determining a defect position. For example, if a secondary electron signal that is subsequently generated upon charging of a second surface contact 22 starts with an unexpectedly high SE yield, the short defect 31 can be identified to be located between the first electrical connection 20 and the second electrical connection 24 that extends from the second surface contact 22. Alternatively or additionally, a reliability value can be included in the output data that is provided by the trained computational model. The reliability value of a detected defect may, for example, be high (e.g., close to 100%), if the SE signal extends far off from the predetermined range 224 or has a gradient that strongly differs from an expected gradient of the SE signals of non-defective electrical connections.

FIG. 2D shows some further examples of secondary electron signals 214 detected as functions of time t during the charging of surface contacts, the surface contacts being connected to a defective electrical connection, respectively. Different defects lead to different SE signals during the charging, respectively. In some embodiments, if a secondary electron signal as a function of time extends out of a predetermined range 224 (illustrated by the grey area in FIG. 2D), the trained computational model may identify the respective electrical connection to be defective. The predetermined range 224 may be defined by the computational model based on the training of the computational model with a plurality of training data sets.

In some embodiments, a respective predetermined range may be defined by the trained computational model for each position identifier of a plurality of position identifiers that characterize the position of a surface contact. The predetermined ranges may be defined by the computational model as a result of the training with a respective multitude of training data sets, wherein each training data set includes an SE signal, a position information (e.g., a position identifier) that identifies the position of the respective surface contact on the substrate, and defect information that specifies whether the respective electrical connection is defective or not.

FIG. 3 schematically illustrates a method of testing a second electrical connection 24 that extends from a second surface contact 22. The second surface contact 22 has a different position identifier than the first surface contact 21 that is tested in FIG. 2A. Specifically, the second surface contact 22 is located—in the sectional plane of FIG. 3—between two neighboring surface contacts, which leads to an increased cross-capacitance that is experienced by the second electrical connection 24 as compared to the first electrical connection 20. As a result, the secondary electron signal 314 generated as a function of time during the charging of the second surface contact 22 is different from the secondary electron signal 114 generated as a function of time during the charging of the first surface contact 21 (see FIG. 2A), assuming that none of the first and second electrical connections is defective.

The secondary electron signal 314 together with the respective position identifier characterizing the position of the second surface contact 22 are provided as part of the input data to the trained computational model, and the trained computational model provides defect information (here: “no defect”) about the second electrical connection 24 as output. In particular, the trained computational model may identify that no defect is present, if the secondary electron signal 314 is within a predetermined range that is defined for surface contacts with a respective position identifier.

In some embodiments, which can be combined with other embodiments described herein, the computational model is configured to define, based on training data sets for each position identifier of a plurality of position identifiers that respectively characterize a position of one or more surface contacts, a respective predetermined range that can be compared with a secondary electron signal measured during charging of a surface contact having the respective position identifier for determining whether the surface contact is connected to a defective electrical connection or not.

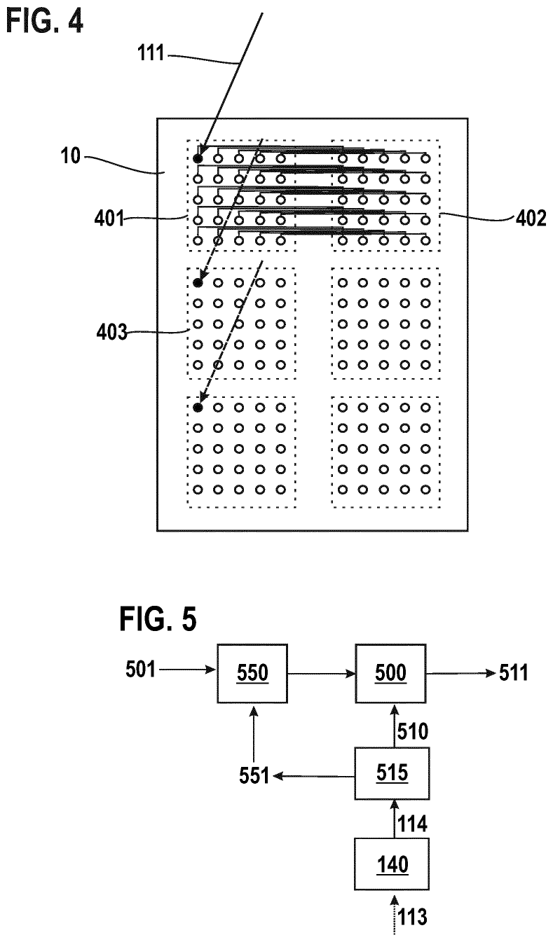

FIG. 4 schematically illustrates a method of identifying defective electrical connections of a substrate 10 according to embodiments described herein. The substrate 10 may be a PLP substrate including a plurality of chip sites 401, 402, 403 each configured for the placement of a respective chip, and 1,000 or more device-to-device electrical interconnect paths may extend from each chip site to one or more other chip sites through the PLP substrate. For example, the substrate may include two, three or more pairs of associated chip sites, and 1,000 or more device-to-device electrical interconnect paths (having optionally exactly two surface contact points, namely one in each chip site of a pair) may extend between the chip sites of each pair through the packaging substrate, as it is schematically depicted in FIG. 4 for the upper pair of chip sites.

Each surface contact of the plurality of surface contacts located at a first chip site 401 may have a corresponding position identifier. Surface contacts arranged at corresponding positions at different chip sites may have corresponding position identifiers. For example, the three surface contacts illustrated as black circles in FIG. 4 that are respectively arranged at upper left corners of respective chip sites may have corresponding position identifiers, since the electrical characteristics of electrical connections extending therefrom may be similar or essentially identical. Alternatively, each surface contact of a specific substrate type may have a respective position identifier. Secondary electron signals generated upon charging of surface contacts having the same position identifier may have a generally similar or identical behavior as a function of time during charging thereof.

Grouping surface contacts and respective electrical connections according to respective electrical properties that result in similar or identical SE signals upon charging, each group having a respective position identifier, facilitates the training of the computational model and improves the reliability of the defect information provided as output by the computational model. Specifically, the trained computational model can define a characteristic temporal behavior (specifically, a “predetermined range” as explained above) of an SE signal associated to a respective position identifier that is indicative of a specific defect or of a non-defective electrical connection.

FIG. 5 is a block diagram illustrating a method of identifying defective electrical connections utilizing a trained computational model 500 according to embodiments described herein. The trained computational model 500 may be stored in a computer-readable storage medium, e.g. in a computer memory.

According to embodiments described herein, the trained computational model 500 is configured to receive input data 510 including or being based on a secondary electron signal 114 detected as a function of time during charging of a surface contact, and is configured to provide, in response thereto, defect information 511 about an electrical connection that extends from the surface contact as an output.

As is schematically depicted in FIG. 5, secondary electrons 113 are detected by the electron detector 140 during the charging of the surface contact with an electron beam, and the secondary electron signal 114 detected as a function of time during the charging is forwarded to an input data generator 515 that provides the input data 510 based on the secondary electron signal 114. The input data generator 515 may generate the input data 510 based on the secondary electron signal 114 and optionally based on further input parameters, particularly based on position information about a location of the surface contact being tested, in particular a position identifier. The input data 510 may optionally include further information, e.g., information about the substrate and/or information about the electrical connection that may facilitate the identification of defects by the trained computational model 500.

The trained computational model 500 provides the defect information 511 as an output, the defect information 511 indicating whether the electrical connection is defective or not. The defect information may also include a defect class, a defect position and/or a reliability value.

The trained computational model 500 may be generated by a preceding stage of training. Training may include generating a plurality of training data sets 551 and training a computational model 501 with the plurality of training data sets 551, e.g. in a training process 550 that utilizes a machine learning algorithm that may depend on the computational model 501 that is to be trained.

Each training data set of the plurality of training data sets 551 may include input data and the associated defect information determined otherwise. The input data may include or be based on a secondary electron signal detected during the charging of a respective surface contact and may further include position information. The associated defect information can be determined, for example, by conducting generally known voltage contrast measurements.

For example, the associated defect information about a first electrical connection extending from a first surface can be determined via one or more voltage contrast measurements, particularly by probing any of (i) the first surface contact, (ii) one or more second surface contacts that ought to be electrically connected to the first surface contact, and (iii) one or more third surface contacts that ought to be electrically separated from the first surface contact with the electron beam or with a second electron beam. Alternatively or additionally, the associated defect information can be determined “manually” by operator classification.

The input data of each training data set may optionally further include position information about a location of the respective surface contact on the substrate, particularly a position identifier. The input data of each training data set may optionally include further information about the substrate and/or about the respective electrical connection being tested, e.g. a substrate identifier and/or a connection identifier.

In some embodiments, which can be combined with other embodiments described herein, a respective multitude of training data sets is provided for surface contacts having corresponding position information or a corresponding position identifier. In particular, several surface contacts that are arranged at corresponding locations of different sub-areas of the substrate (e.g., of different chip sites) or at corresponding locations of different substrates of the same type are tested for providing a multitude of training data sets for positionally related surface contacts.

The grouping of surface contacts according to respective position identifiers may be beneficial, because surface contacts having corresponding position identifiers may generally have similar electrical properties that may lead to similar or identical SE signals upon charging. The training can be facilitated and more reliable defect information can later be provided by the trained computational model, if the training data sets not only include the respective SE signal, but also the corresponding position information, such that—when used for testing—also the position information about the electrical connection being tested can be used as an input parameter for the trained computational model.

The computational model 501 may be a machine learning model, particularly a deep learning-based model. In some embodiments, the machine learning model may be based on a neural network, particularly on a deep neural network (DNN) having at least one hidden layer, e.g. a deep neural network with three or more layers. Also neural networks with a smaller number of layers can be utilized.

Each layer of the DNN can include multiple basic computational elements (CE) typically referred to in the art as dimensions, neurons, or nodes. Computational elements of a given layer are connected with CEs of a subsequent layer by connections. Each connection between CE of a preceding layer and CE of a subsequent layer may be associated with a weighting value.

A given hidden CE can receive inputs from CEs of a previous layer via the respective connections, each given connection being associated with a weighting value which can be applied to the input of the given connection. The weighting values can determine the relative strength of the connections and thus the relative influence of the respective inputs on the output of the given CE. The given hidden CE can be configured to compute an activation value (e.g. the weighted sum of the inputs) and further derive an output by applying an activation function to the computed activation. The activation function can be, for example, an identity function, a deterministic function (e.g., linear, sigmoid, threshold, or the like), a stochastic function or other suitable function. The output from the given hidden CE can be transmitted to CEs of a subsequent layer via the respective connections. Likewise, each connection at the output of a CE can be associated with a weighting value which can be applied to the output of the CE prior to being received as an input of a CE of a subsequent layer. Further to the weighting values, there can be threshold values (including limiting functions) associated with the connections and CEs.

The weighting and/or threshold values of a neural network can be initially selected prior to training, and can be further iteratively adjusted or modified during the training to achieve an optimal set of weighting and/or threshold values in the trained computational model. A set of DNN input data used to adjust the weights/thresholds of the computational model is referred to herein as a training data set.

It is noted that the teachings of the testing methods disclosed herein are not bound by the number of hidden layers and/or by the DNN architecture. By way of a non-limiting example, the layers in DNN can be convolutional, fully connected, locally connected, pooling/subsampling, recurrent, etc. In some examples, the computational model is an if-else-based model. For example, the computational model may define, for each position identifier, a predetermined range, in which respective SE signals are expected to lie if the respective electrical connection is not defective. If-during the testing-a measured SE signal lies in the predetermined range, the trained computational model recognizes “no defect”, otherwise, the trained computational model recognizes “defect”.

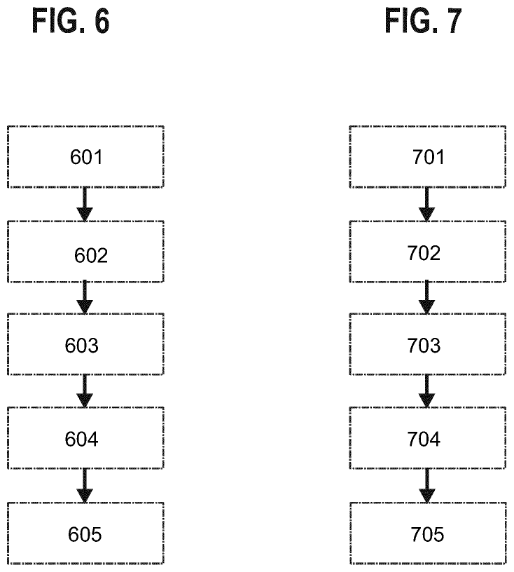

FIG. 6 is a flowchart illustrating a method of identifying defective electrical connections according to embodiments described herein.

In box 601, a first surface contact being tested is charged by directing an electron beam on the first surface contact.

In box 602, a first secondary electron signal is detected as a function of time during the charging.

In box 603, input data is generated based on the detected first electron signal. Specifically, the input data may not only include the first electron signal (or parts or characteristics thereof), but also further information, such as position information about the first surface contact, e.g. a position identifier that characterizes the position of the first surface contact on the substrate surface. The input data is input to a trained computational model, particularly to a trained machine learning model.

In box 604, defect information about the first electrical connection is received as an output from the trained computational model. The defect information may indicate whether the first electrical connection is defective, and—if so—may further include any of a defect class, a defect position and/or a reliability value.

The method may proceed in box 605 by deflecting the electron beam to impinge on a second surface contact for charging and testing a second electrical connection that extends from the second surface contact. The second electrical connection may be inspected in analogy to the first electrical connection.

Optionally, any of the surface contacts may be discharged before and/or after the charging, in order to avoid an accumulation of charges on the substrate that may negatively affect the defect detection.

FIG. 7 is a flowchart illustrating a method of generating a trained computational model for identifying defective electrical connections according to embodiments described herein.

In box 701, a first surface contact is charged by directing an electron beam on the first surface contact.

In box 702, a first secondary electron signal is detected as a function of time during the charging.

In box 703, associated defect information about a first electrical connection that extends from the first surface contact is determined. The associated defect information may be retrieved via one or more voltage contrast measurements. For example, the first surface contact, one or more second surface contacts that ought to be electrically connected to the first surface contact, and/or one or more third surface contacts that ought to be electrically separated from the first surface contact may be probed, e.g. with the electron beam or with a second electron beam. An “open” defect can be determined if the first surface contact and one or more second surface contacts are not provided on the same electrical potential. A “short” defect can be determined if the first surface contact and one or more third surface contacts are provided on the same electrical potential.

In box 704, a first training data set is provided that includes input data and the associated defect information determined in box 703. The input data includes or is based on the secondary electron signal and optionally further information, such as position information about the first surface contact.

In box 705, the trained computational model is generated by training a computational model with the first training data set provided in box 704, particularly utilizing a machine learning algorithm.

A plurality of further training data sets may be provided in analogy to the first training data set by testing a plurality of further surface contacts having a respective electrical connection extending therefrom, and the machine learning model may be trained with the plurality of further surface contacts. In particular, a plurality of surface contacts having a same position identifier may be tested for providing respective training data sets including said position identifier as a parameter. Using position identifiers as an input parameter for the trained computational model during the testing improves the reliability of the defect information, because the electrical characteristics of electrical connections (and therefore the time dependency of the SE yield) may strongly depend on the position of the tested surface contact on the substrate.

The trained machine learning model may be further improved over time, e.g. utilizing a self-learning algorithm, by training with further training data sets that may be generated during the use of the trained computational model for defect inspection and classification.

According to embodiments described herein, methods of quickly and reliably identifying defective electrical connections of a substrate are provided that use a trained computational model, particularly a trained machine learning model and deep-learning based algorithms. A secondary electron signal that is measured as a function of time during the charging of a respective surface contact is used as an input parameter for the trained computational model. Further input parameters, such as a position information about the surface contact being tested may be given to the trained machine learning model. The use of artificial intelligence and machine learning techniques for detecting defective electrical connections improves the defect detectability and provides a higher defect classification accuracy and purity as compared to conventional electron beam inspection techniques based on voltage contrast measurements. The computational model may be improved over time by training with further training data sets, such that a self-learning and a self-improving algorithm of defect detection can be provided. The methods described herein can be applied for the testing of complex substrates, particularly AP substrates and/or PLP substrates, having a huge number of electrical connections, wherein the SE signals generated during charging may depend on a plurality of parameters, including the position of the surface contact being testing on the substrate.

While the foregoing is directed to some embodiments, other and further embodiments may be devised without departing from the basic scope thereof, and the scope thereof is determined by the claims that follow.

1. A method of identifying defective electrical connections of a substrate, the substrate having a first surface contact and a first electrical connection extending from the first surface contact, the method comprising:
charging the first surface contact by directing an electron beam on the first surface contact;
detecting a first secondary electron signal as a function of time during the charging of the first surface contact;
inputting input data that comprise or are based on the first secondary electron signal to a trained computational model; and
receiving defect information about the first electrical connection as an output from the trained computational model.

2. The method of claim 1, wherein the input data that are input to the trained computational model further comprise position information about the first surface contact.

3. The method of claim 2, wherein the position information comprises at least one of an absolute position of the first surface contact on the substrate, a relative position of the first surface contact with respect to one or more further surface contacts, and a position identifier.

4. The method of claim 1, wherein the input data that are input to the trained computational model further comprise any one or more of the following information:
information about the substrate including at least one of a substrate type, a substrate material, one or more substrate layer materials, a substrate design rule, and a substrate identifier; and
information about the first electrical connection, including at least one of a capacitance value, a cross-capacitance value, a number of surface contacts that are connected to the first electrical connection, a number of neighboring surface contacts, and a connection identifier.

5. The method of claim 1, wherein the defect information about the first electrical connection comprises any one or more of:
information as to whether the first electrical connection comprises a defect or not, a defect class, a defect location, and
a reliability value.

6. The method of claim 1, wherein the substrate has a plurality of surface contacts with a respective electrical connection extending therefrom, and wherein (a), (b), (c), (d) are conducted for each surface contact of the plurality of surface contacts for obtaining defect information about the respective electrical connection.

7. The method of claim 6, wherein the substrate is a panel-level packaging substrate or an advanced packaging substrate, and the plurality of surface contacts comprises 1,000,000 or more surface contacts.

8. The method of claim 6, wherein the plurality of surface contacts are distributed over a surface area of the substrate of 16 cm² or more, the method further comprising deflecting the electron beam with a scan deflector on the plurality of surface contacts for successively charging and testing the plurality of surface contacts.

9. The method of claim 1, further comprising generating the trained computational model by training a computational model with a plurality of training data sets that respectively comprise input data and associated defect information about a respective electrical connection, wherein the input data respectively comprise or are based on a secondary electron signal detected as a function of time during charging of a surface contact from which the respective electrical connection extends.

10. The method of claim 9, wherein the input data respectively further comprise position information about the surface contact.

11. A method of generating a trained computational model for identifying defective electrical connections of a substrate, comprising:
charging a first surface contact by directing an electron beam on the first surface contact;
detecting a secondary electron signal as a function of time during the charging of the first surface contact;
determining associated defect information about a first electrical connection that extends from the first surface contact;
providing a first training data set comprising input data that includes or is based on the secondary electron signal and the associated defect information; and
generating the trained computational model by training a computational model with the first training data set and with a plurality of further training data sets provided analogously for a plurality of further surface contacts having a respective electrical connection extending therefrom.

12. The method of claim 11, wherein the associated defect information about the first electrical connection is determined via one or more voltage contrast measurements.

13. The method of claim 11, wherein the input data of the first training data set further comprises position information about a location of the first surface contact on the substrate.

14. The method of claim 11,
wherein a respective multitude of training data sets is provided for surface contacts having corresponding position information or a corresponding position identifier.

15. The method of claim 11, wherein the trained computational model is a trained machine learning model or a trained deep learning-based model based on a deep neural network having at least one hidden layer.

16. An apparatus for identifying defective electrical connections of a substrate, comprising:
a vacuum chamber that houses a stage for placement of the substrate;
an electron source configured to generate an electron beam; a scan deflector for directing the electron beam on a first surface contact for charging the first surface contact;
an electron detector configured to detect a first secondary electron signal as a function of time during the charging of the first surface contact; and a data processing unit with a memory storing a trained computational model that is configured to receive input data comprising or being based on the first secondary electron signal and to provide defect information about a first electrical connection that extends from the first surface contact as an output.

17. The apparatus of claim 16, wherein the scan deflector is configured to provide a deflection area of 16 cm² or more.

18. The apparatus of claim 16, further comprising a discharging device for discharging at least a portion of the substrate.

19. The apparatus of claim 16 that is configured to perform the method of claim 1.

20. A computer-readable storage medium storing a trained computational model configured to receive input data comprising or being based on a secondary electron signal detected as a function of time during charging of a surface contact, and provide, in response thereto, defect information about an electrical connection that extends from the surface contact as an output.

21. The computer-readable storage medium of claim 20, wherein the trained computational model is generated in accordance with claim 11.

22. The method of claim 1, wherein the trained computational model is a trained machine learning model or a trained deep learning-based model based on a deep neural network having at least one hidden layer.
